(19) United States
(12) Patent Application Publication
(10) Pub. No.: US 2021/0270887 A1
(43) Pub. Date: Sep. 2, 2021

(54) Method for determining the service life of a semiconductor power module

(71) Applicant: Schaeffler Technologies AG & Co. KG, Herzogenaurach (DE)

(72) Inventors: Johannes Herrmann, Achern (DE); Jürgen Tipper, Gernsbach (DE)

(73) Assignee: Schaeffler Technologies AG & Co. KG, Herzogenaurach (DE)

(21) Appl. No.: 17/253,153

(22) PCT Filed: May 22, 2019
(86) PCT No.: PCT/DE2019/100454

§ 371 Date: Dec. 17, 2020

(30) Foreign Application Priority Data
Jun. 26, 2018 (DE) 10 2018 115 312.0

(51) Int. Cl. G01R 31/26; G05B 17/02; G01K 3/08; G01K 7/42

(52) U.S. Cl. CPC G01R 31/2642; G01K 7/42; G01K 3/08; G05B 17/02

(57) ABSTRACT

A method determines the service life of a semiconductor power module, which controls an electric motor in a drive train of a vehicle. A temperature of the semiconductor power module is determined by means of a temperature model. A measured temperature of the semiconductor power module is compared with the temperature of the semiconductor power module determined by means of the temperature model and the status of the service life of the semiconductor power module is inferred from the comparison of the two temperatures.

### CROSS-REFERENCE TO RELATED APPLICATIONS

This application is the U.S. National Phase of PCT Appin. No. PCT/DE2019/100454 filed May 22, 2019, which claims priority to DE 102018115312.0 filed Jun. 26, 2018, the entire disclosures of which are incorporated by reference herein.

### TECHNICAL FIELD

The disclosure relates to a method for determining the service life of a semiconductor power module, which controls an electric motor in a drive train of a vehicle, wherein a temperature of the semiconductor power module is determined by means of a temperature model.

### BACKGROUND

From DE 10 2014 216 310 A1, a method for determining a temperature of power and control electronics of an electrical drive system is known, wherein the drive system preferably comprises an electric motor. In the method in which non-measurable temperatures of the thermally relevant electronic components of the power and drive electronics can be easily determined, the at least one temperature of the power and drive electronics is calculated from a model with concentrated temperature parameters corresponding to the thermal system structure of the power and control electronics. Since the thermal capacitances and resistances are considered constant over the entire service life of the power and control electronics in the model, it cannot be anticipated when the semiconductor power modules will have to be replaced if they have become inoperable.

### SUMMARY

It is desirable to have a method for determining the service life of a semiconductor power module, in which the time at which the power semiconductor module is replaced can be perspectively determined.

In the method disclosed herein, a measured temperature of the semiconductor power module is compared with the temperature of the semiconductor power model determined by means of the temperature model and the status of the service life of the semiconductor power module is inferred from the comparison of the two temperatures. The status of the service life is thus determined using the available temperature sensor. The sole additional use of a temperature sensor allows the status of the service life of the power semiconductor module to be implemented with only a small amount of technical construction. Knowledge of the status of the service life represents a great potential for cost savings, wherein the service life of the semiconductor power modules can be practically fully utilized. Repairs that are required at the same time can be scheduled in a targeted manner, since the replacement of the semiconductor power module can be determined in advance.

Advantageously, a difference is formed for comparison from the measured temperature and the temperature determined by means of the temperature model, which is used as information about the status of the service life. Since the temperature, which is determined by means of the temperature sensor, changes over the service life as a result of the fact that the electrical and thermal properties of the semiconductor power module change, a cost-effective statement about the service life of the semiconductor power module is possible by means of the difference.

In one embodiment, the difference corresponds to a thermal resistance between the semiconductor power module and a reference variable of the power semiconductor module, the change of which is used to assess the status of the service life. The feature of the thermal resistance between the power semiconductor and the reference represents an important technical feature of the semiconductor power module and is therefore particularly suitable for determining the status of the service life.

In one embodiment, a coolant temperature of the semiconductor power module is used as a reference variable. In contrast to this, since this coolant has a constant temperature, the thermal resistance of the semiconductor power module can be determined particularly reliably.

In one variant, the temperature model is based on an unchangeable thermal output state of the semiconductor power module, wherein the measured temperature of the semiconductor power module is determined during operation of the vehicle when installed in the drive train. Since only the measured temperature changes over the service life, reliable conclusions can be drawn about the thermal resistance of the semiconductor power module.

In a further development, the temperature model describes heat sources, heat sinks, heat resistances and heat capacities of the power semiconductor module. Various influences are thus taken into account when determining the temperature of the semiconductor power module using the temperature model.

In a further embodiment, before use in the vehicle, a thermal relationship within the semiconductor power module and a change in the thermal resistance of the semiconductor power module over the service life is determined by measurement when qualifying the semiconductor power module and evaluating the status of the service life of the semiconductor power module is based thereon. Through the predictive determination of the thermal relationship and the thermal resistance, characteristic curves can be created that can be compared with the current status of the semiconductor power module during operation of the drive train, from which the current status of the service life of the power semiconductor module in operation can be inferred.

### BRIEF DESCRIPTION OF THE DRAWINGS

One embodiment will be explained in more detail with reference to the figures shown in the drawing.

In the figures:

FIG. 1 shows an exemplary embodiment of a temperature model of a semiconductor power module,

FIG. 2: shows an exemplary embodiment of the method,

FIG. 3 shows a simulation of the status of the power semiconductor module between the delivery state and at the end of its service life.

### DETAILED DESCRIPTION

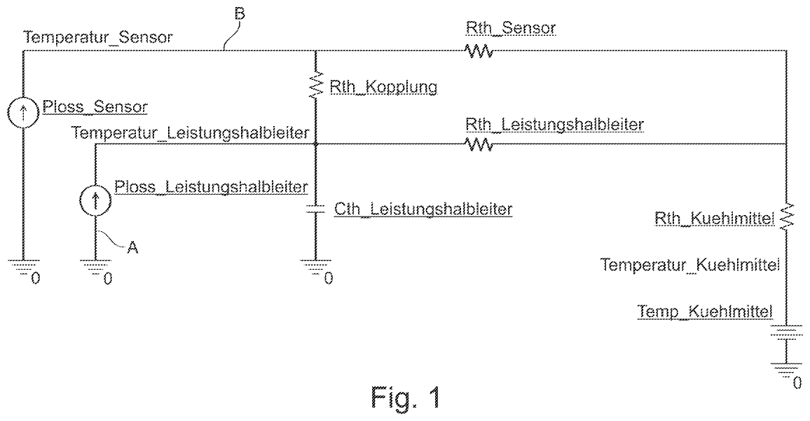

FIG. 1 shows an exemplary embodiment of a temperature model of a semiconductor power module, by means of which the thermal impedance of the power semiconductor module is shown. This power semiconductor module consists of heat sources and heat sinks. A path A of the semiconductor power module is shown, which, like the path B, reflects the temperature output by the temperature sensor, indicates temp-coolant to the coolant temperature. The path A of the semiconductor power module has, as a heat source, a power loss Ploss power semiconductor of the semiconductor power module, which influences the heat resistance of the power semiconductor. In contrast, the path B, which shows the temperature of the temperature sensor, shows a self-heating Ploss sensor of the temperature sensor as a heat source. The paths A and B are coupled via a heat resistance Rth_coupling, to which a thermal capacity Cth_power semiconductor of the power semiconductor module is connected in series. The two paths A and B end in a path C, in which the heat resistance Rth_is provided for the coolant connection, which ends in the coolant temperature temp_coolant as a reference parameter.

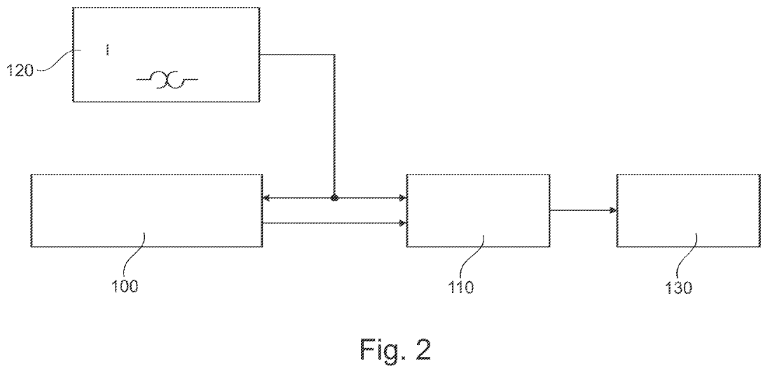

FIG. 2 shows an exemplary embodiment of the method. The temperature of the semiconductor power module determined by means of the temperature model 100 in FIG. 1, which describes the delivery state of the semiconductor power module before installation in the vehicle and is used unchanged over the service life of the semiconductor power module, is fed to a comparator 110. During the operation of the drive train of the vehicle, a temperature sensor measures the actual temperature of the semiconductor power module on the semiconductor power module installed in the drive train in the block 120 and feeds this to both the temperature model in the block 100 and the comparator in the block 110. The temperature of the semiconductor power module supplied to the comparator 110 from the temperature model in the block 100 thus only changes on the basis of the influence of the temperature actually measured on the power semiconductor module. The comparator 110 forms a difference from the measured temperature and the temperature determined by the temperature model (block 130). The measured temperature represents the actual temperature, and the temperature determined with the temperature model represents the target temperature. The difference between these two temperatures corresponds to the deterioration in the heat resistance of the semiconductor power module to the coolant and thus to the aging of the semiconductor power module, since the electrical and thermal properties deteriorate over the service life of the semiconductor power module.

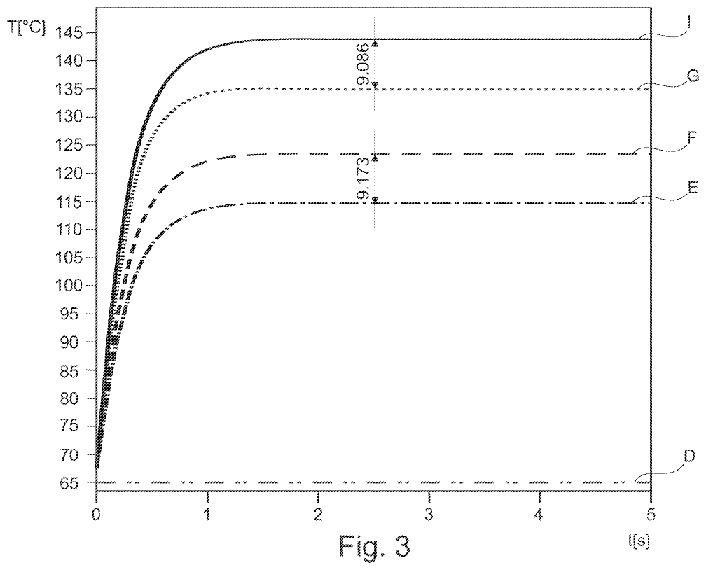

FIG. 3 shows an exemplary embodiment for a simulation of the proposed method. This graph shows the temperature T over time t. The curve D represents the temperature of the coolant, which is constantly regulated. The curve E shows the temperature of the temperature sensor in the delivery state of the power semiconductor module, and the curve F shows the temperature of the temperature sensor at the end of the service life of the power semiconductor module. The curves are roughly between 112 and 121° C. The curve G illustrates the temperature of the semiconductor power module calculated by the temperature model in the delivery state, while the temperature curve I above it shows the temperature at the end of the service life of the semiconductor power module. In both cases, similar temperature differences are determined, which can be used to infer the state of aging of the power semiconductor. These temperature differences between the current temperature measured by the temperature sensor and the temperature specified by the temperature model are compared with a characteristic curve that was determined by monitoring a service life of a semiconductor power module that was evaluated by measurement in the unassembled state in order to provide information about the status of the service life of the installed semiconductor power module.

Various statements can be made using the status of the service life, for example for how long it is still possible to drive electrically using these power semiconductor modules. However, the load cycle can also be recognized in advance in order to optimally utilize the power semiconductor modules installed in the drive train. The solution described can advantageously be used for electric axle drives as well as for hybrid modules as well as electric wheel hub drives and electrified hybrid drives. This solution can also be used for small drives such as roll stabilizers, regardless of the semiconductor technology on which the semiconductor power module is based.

1. A method for determining the service life of a semiconductor power module which controls an electric motor in a drive train of a vehicle, wherein a temperature of the semiconductor power module is determined by means of a temperature model, and wherein a measured temperature of the semiconductor power module is compared with the temperature of the semiconductor power module determined by means of the temperature model and the status of the service life of the semiconductor power module is inferred from the comparison of the two temperatures.

2. The method according to claim 1, wherein a difference is formed from the measured temperature and the temperature determined by means of the temperature model, which is used as information about the status of the service life.

3. The method according to claim 2, wherein the difference corresponds to a thermal resistance between the power semiconductor module and a reference variable of the power semiconductor module, the change of which is used to assess the status of the service life.

4. The method according to claim 3, wherein a coolant temperature of the semiconductor power module is used as a reference variable.

5. The method according to claim 1, wherein the temperature model is based on an unchangeable thermal output state of the semiconductor power module, wherein the measured temperature of the semiconductor power module is determined during operation of the vehicle when installed in the drive train.

6. The method according to claim 1, wherein the temperature model describes heat sources, heat sinks, heat resistances and heat capacities of the power semiconductor module.

7. The method according to claim 1, wherein a thermal relationship within the semiconductor power module and a change in the thermal resistance of the semiconductor power module over the service life is determined by measurement when qualifying the semiconductor power module before use in the vehicle, and evaluating the status of the service life of the semiconductor power module is based thereon.
